(19) United States
(12) Patent Application Publication
(10) Pub. No.: US 2021/0181766 A1
(43) Pub. Date: Jun. 17, 2021

(54) RETURN FLIGHT CONTROL METHOD AND DEVICE, AND UNMANNED AERIAL VEHICLE

(71) Applicant: SZ DJI TECHNOLOGY CO., LTD., Shenzhen (CN)

(72) Inventors: Chang GENG, Shenzhen (CN); Xinjun LIU, Shenzhen (CN); Zhaoliang PENG, Shenzhen (CN); Zhenzhou LAI, Shenzhen (CN)

(21) Appl. No.: 17/180,534

(22) Filed: Feb. 19, 2021

Related U.S. Application Data
(63) Continuation of application No. PCT/CN2018/101958, filed on Aug. 23, 2018.

(51) Int. Cl. G05D 1/10; B64C 39/02; G08G 5/00; G08G 5/02

(52) U.S. Cl. CPC G05D 1/101; B64C 39/024; B64C 2201/14; G08G 5/025; G08G 5/0069

(57) ABSTRACT

The present disclosure provides a method for controlling a return flight of an unmanned aerial vehicle (UVA). The method includes controlling the UAV to fly to a predetermined cruising altitude, and controlling the UAV to return horizontally at the predetermined cruising altitude based on a first predetermined horizontal speed control value when determining that a remaining power of the UVA is less than or equal to a predetermined return flight power threshold; and controlling the UAV to perform a forced landing and the return flight based on the first predetermined horizontal speed control value and a predetermined descent speed control value when determining that the remaining power of the UAV is less than or equal to a predetermined descent power threshold in the process of the horizontal return at the predetermined cruising altitude.

### CROSS-REFERENCE TO RELATED APPLICATION

This application is a continuation of International Application No. PCT/CN2018/101958, filed on Aug. 23, 2018, the entire content of which is incorporated herein by reference.

### TECHNICAL FIELD

The present disclosure relates to the technical field of control technology and, more specifically, to a return flight control method and device, and an unmanned aerial vehicle (UAV).

### BACKGROUND

UAVs that use smart batteries have the function of return flight with smart power. However, due to the technical constraints and/or environmental factors, the power calculated by the UAV is prone to errors that make it difficult to operate the return flight successfully. In view of this problem, the conventional technical solution is to increase the power reserved for the return flight. However, it is difficult to control the amount of power with the method of increasing the return flight power reserved. If there is too much power reserved, the user experience can be affected. If the reserved power is insufficient, the UAV cannot operate the return flight successfully, and the UAV can be easily lost. Therefore, effectively controlling the return flight of the UAV is of greater importance.

### SUMMARY

One aspect of the present disclosure provides a method for controlling a return flight of an unmanned aerial vehicle (UVA). The method includes controlling the UAV to fly to a predetermined cruising altitude, and controlling the UAV to return horizontally at the predetermined cruising altitude based on a first predetermined horizontal speed control value when determining that a remaining power of the UVA is less than or equal to a predetermined return flight power threshold; and controlling the UAV to perform a forced landing and the return flight based on the first predetermined horizontal speed control value and a predetermined descent speed control value when determining that the remaining power of the UAV is less than or equal to a predetermined descent power threshold in the process of the horizontal return at the predetermined cruising altitude.

Another aspect of the present disclosure provides A device for controlling a return flight of an UAV. The device includes a processor; and a memory storing program instructions that, when being executed by the processor, cause the processor to: control the UAV to fly to a predetermined cruising altitude, and control the UAV to return horizontally at the predetermined cruising altitude based on a first predetermined horizontal speed control value when determining that a remaining power of the UVA is less than or equal to a predetermined return flight power threshold; and control the UAV to perform a forced landing and the return flight based on the first predetermined horizontal speed control value and a predetermined descent speed control value when determining that the remaining power of the UAV is less than or equal to a predetermined descent power threshold in the process of the horizontal return at the predetermined cruising altitude.

### BRIEF DESCRIPTION OF THE DRAWINGS

In order to illustrate the technical solutions in accordance with the embodiments of the present disclosure more clearly, the accompanying drawings to be used for describing the embodiments are introduced briefly in the following. It is apparent that the accompanying drawings in the following description are only some embodiments of the present disclosure. Persons of ordinary skill in the art can obtain other accompanying drawings in accordance with the accompanying drawings without any creative efforts.

FIG. 1 is a schematic structural diagram of a UAV return flight control system according to an embodiment of the present disclosure.

FIG. 2A is a schematic diagram of a conventional UAV return flight method.

FIG. 2B is a schematic diagram of a return flight power estimation method in conventional technology when the power is insufficient.

FIG. 2C is a schematic diagram of a UAV forced landing and return flight method according to an embodiment of the present disclosure.

FIG. 3 is a flowchart of a UAV return flight control method according to an embodiment of the present disclosure.

FIG. 4A is a schematic diagram of another UAV forced landing and return flight method according to an embodiment of the present disclosure.

FIG. 4B is a schematic diagram of another UAV forced landing and return flight method according to an embodiment of the present disclosure.

FIG. 4C is a schematic diagram of another UAV forced landing and return flight method according to an embodiment of the present disclosure.

FIG. 4D is a schematic diagram of another UAV forced landing and return flight method according to an embodiment of the present disclosure.

FIG. 5 is a flowchart of a UAV return flight power estimation method according to an embodiment of the present disclosure.

FIG. 6 is a flowchart of a method for establishing a UAV power consumption model per unit of time according to an embodiment of the present disclosure.

FIG. 7A is an effective diagram of an estimated power consumption per unit of time at a predetermined cruising altitude according to an embodiment of the present disclosure.

FIG. 7B is an effective diagram of an estimated power consumption per unit of time during a forced landing and return flight according to an embodiment of the present disclosure.

FIG. 8 is a schematic structural diagram of a UAV return flight control device according to an embodiment of the present disclosure.

FIG. 9 is a schematic structural diagram of a structure of a return flight power estimation device for a UAV according to an embodiment of the present disclosure.

FIG. 10 is a schematic structural diagram of a device for establishing a UAV power consumption model per unit of time according to an embodiment of the present disclosure.

### DETAILED DESCRIPTION OF THE EMBODIMENTS

Technical solutions of the present disclosure will be described in detail with reference to the drawings. It will be appreciated that the described embodiments represent some, rather than all, of the embodiments of the present disclosure. Other embodiments conceived or derived by those having ordinary skills in the art based on the described embodiments without inventive efforts should fall within the scope of the present disclosure.

Exemplary embodiments will be described with reference to the accompanying drawings. In the case where there is no conflict between the exemplary embodiments, the features of the following embodiments and examples may be combined with each other.

The UAV return flight control method provided in the embodiments of the present disclosure can be executed by a UAV return flight control system, and the UAV return flight control system and the UAV can perform two-way communication. The UAV return flight control system may include a UAV return flight control device and the UAV. In some embodiments, the UAV return flight control device can be disposed on the UAV. In some embodiments, the UAV return flight control device can be spatially independent from the UAV. In some embodiments, the UAV return flight control device can be a component of the UAV, that is, the UAV may include the UAV return flight control device. In other embodiments, the UAV return flight control method can also be applied to other movable devices, such as robots capable of autonomous movement, unmanned vehicles, unmanned ships, and other movable devices.

The UAV return flight control device in the UAV return flight control system can obtain the UAV's remaining power in real time during the movement of the UAV. When it is determined that the remaining power of the UAV is less than or equal to a predetermined return flight power threshold, the UAV return flight control device can control the UAV to fly to a predetermined cruising altitude and control the UAV to return flight horizontally at a return flight altitude based on a first predetermined horizontal speed control value. When the UAV returns horizontally at the predetermined cruising altitude, if the UAV return flight control device determines that the UAV's remaining power is less than or equal to a predetermined descent power threshold, the UAV can be controlled to perform a forced landing and return flight based on the first predetermined horizontal speed control value and the predetermined descent speed control value. By using this method, the descent time of the UAV can be reduced, the possibility of the UAV returning when the battery is in sufficient can be improved, the probability of losing the UAV can be reduced, and the accuracy and flight safety of the UAV's return flight can be improved. The following is a description of the UAV return flight control system provided in the embodiments of the present disclosure.

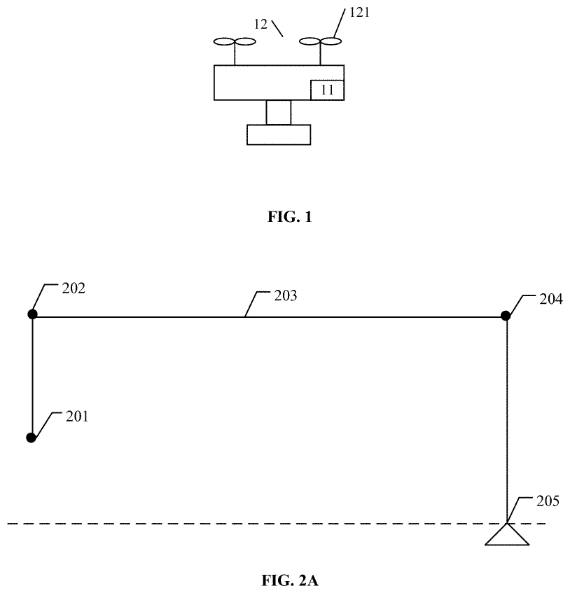

Referring to FIG. 1, which is a schematic structural diagram of a UAV return flight control system according to an embodiment of the present disclosure. The UAV return flight control system includes a UAV return flight control device 11 and a UAV 12. In some embodiments, the UAV 12 and the UAV return flight control device 11 may establish a communication connection through a wireless communication connection. In some specific scenarios, a communication connection between the UAV 12 and the UAV return flight control device 11 may also be established through a wired communication connection. In some embodiments, the UAV return flight control device 11 may be a flight controller. The UAV 12 may be a rotary-wing aircraft, such as a quad-rotor aircraft, a hexa-rotor aircraft, an eight-rotor aircraft, or a fixed-wing aircraft. The UAV 12 includes a power system 121, and the power system 121 can be used to provide power for the UAV 12 to fly.

In this embodiment, the UAV return flight control device 11 may obtain the remaining power of the UAV 12 in real time, and when it is determined that the remaining power of the UAV 12 is less than or equal to the predetermined return flight power threshold, the UAV 12 can be controlled to fly to the predetermined cruising altitude, thereby controlling the UAV 12 to return horizontally at the predetermined cruising altitude based on the first predetermined horizontal speed control value. When the UAV 12 is returning horizontally at the predetermined cruising altitude, when the UAV return flight control device 11 determines that the remaining power of the UAV 12 is less than or equal to the predetermined descent power threshold, the UAV return flight control device 11 can control the UAV 12 to perform a forced landing and return the flight based on the first predetermined horizontal speed control value and the predetermined descent speed control value.

In one embodiment, the UAV 12 may obtain the current position of the UAV 12 in real time during the flight, and calculate the return flight power needed for the UAV 12 to return from the current position to a home point, that is, the return flight power amount, and determine a predetermined return flight power threshold based on the return flight power amount. In some embodiments, the return flight power can be calculated by a return flight power estimation method provided in the later part of the present disclosure, and the UAV return flight control device 11 can perform the return flight power estimation method described later in the present disclosure. In some embodiments, the UAV 12 may obtain the current altitude of the UAV 12 in real time, calculate the amount of power that the UAV 12 needs to descend from the current altitude to the ground, that is, the descent power, and determine the predetermined descent power threshold based on the descent power. In some embodiments, both the predetermined return flight power threshold and the predetermined descent threshold may include a safety margin.

In one embodiment, when it is determined that the remaining power of the UAV 12 is less or equal to the predetermined return flight power threshold, the UAV 12 can be trigger to perform the return flight. The UAV 12 can be controlled to fly to the predetermined cruising altitude, and the UAV 12 can be controlled to return horizontally at the predetermined cruising altitude based on the first predetermined horizontal speed control value.

In one embodiment, when the UAV 12 is returning horizontally at the predetermined cruising altitude, when the return flight control device 11 of the UAV 12 determines that the remaining power of the UAV 12 is less or equal to the predetermined descent power threshold, the UAV return flight control device 11 may control the UAV 12 to perform a forced landing and return the flight based on the first predetermined horizontal speed control value and the predetermined descent speed control value.

In one embodiment, when the UAV is performing the forced landing and return flight, the downward speed component, that is, the predetermined descent speed control value, may be added to the first predetermined horizontal speed control value, such that the UAV 12 can perform the return flight while descending horizontally to reduce the descend time. When the UAV 12 descends to a predetermined safe altitude, it may stop the descent, and the UAV 12 may return the flight horizontally at the predetermined safe altitude to prevent to the UAV from hitting the ground and improving the safety of the UAV. When the UAV 12 returns horizontally at the predetermined safe altitude, if the remaining power of the UAV 12 is less than or equal to a predetermined landing power threshold, the UAV can be controlled to land, thereby further improving the safety of the UAV. In some embodiments, the UAV 12 may obtain the current altitude of the UAV 12 in real time, calculate the landing power needed for the UAV 12 to land from the current altitude to the ground, that is, the landing power, and determined the predetermined landing power threshold based on the landing power. In some embodiments, the value of the predetermined landing power threshold may include a small margin.

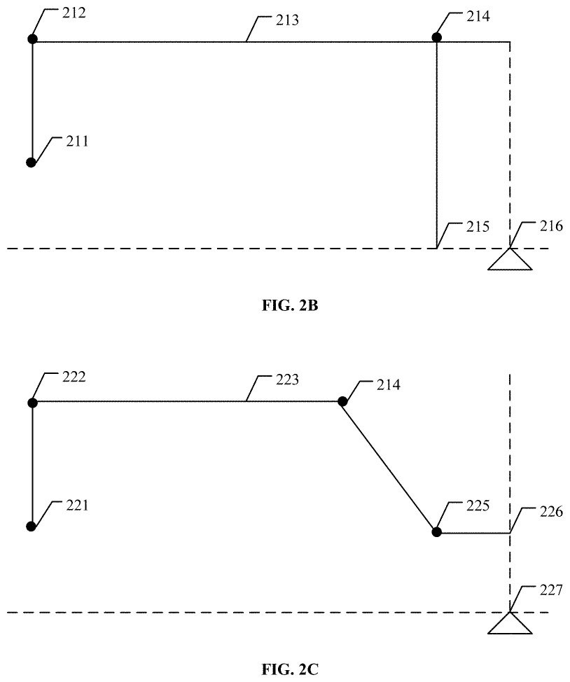

In some embodiments, the embodiments of the present disclosure may be based on the conventional return flight method in the conventional technology shown in FIG. 2A and FIG. 2B. The return flight method provided by the embodiments of the present disclosure will be described in comparison with the return flight method as shown in FIG. 2C provided by an embodiment of the present disclosure.

FIG. 2A is a schematic diagram of a conventional UAV return flight method. FIG. 2A includes a return flight starting point 201, a cruising altitude point 202, a horizontal return flight route 203, a descent point 204, and a return flight point 205. Then conventional UVA return flight method generally adopts a straight return flight, and then descends after reaching the return flight point. As shown in FIG. 2A, the UAV ascends to the cruising altitude point 202 at the return flight starting point 201, and returns horizontally along the horizontal return flight route 203 to the descent point 204. In some embodiments, the descent point 204 may be positioned directly above the return flight point 205, and the UAV may begin to descend at the descent point 204 and land at the return flight point 205, where the return flight point 205 may be set on the ground. This return flight method is achieved by setting the predetermined return flight power threshold to a larger power threshold. This return flight method needs a higher amount of the remaining power of the UAV, that is, the UAV needs to have more remaining power when the UAV enters the return flight mode, which will reduce the amount of power of the UAV takes to perform tasks and affect user experience.

FIG. 2B is a schematic diagram of a return flight power estimation method in conventional technology when the power is insufficient. FIG. 2B includes a return flight starting point 211, a cruising altitude point 212, a horizontal return flight route 213, a descent point 214, and a return flight point 215. As shown in FIG. 2B, the UAV ascends to the cruising altitude point 212 at the return flight starting point 211, and returns horizontally along the horizontal return flight route 213. When the UAV returns horizontally to the descent point 214, the remaining power may be less than the predetermined descent power threshold, and the UAV may begin to descend at the descent point 214 and land at the return flight point 215, where the return flight point 215 may be in front of a return flight point 216. This return flight method estimates the amount of return flight power based on the conventional return flight power estimation method, such that the estimated return flight power may be insufficient, and the predetermined return flight power threshold may be set to a relatively small power threshold. Therefore, when the UAV enters the return flight mode, the remaining power may be insufficient, such that the UAV may land before flying to the return flight point, which may easily cause the UAV to be lost.

FIG. 2C is a schematic diagram of a UAV forced landing and return flight method according to an embodiment of the present disclosure. FIG. 2C includes a return flight starting point 221, a cruising altitude point 222, a horizontal return flight route 223, a descent point 224, a safe altitude point 225, a landing point 226, and a return flight point 227. In view of the situations described above, an embodiment of the present disclosure provides a UAV return flight control method shown in FIG. 2C. This method can control the UAV to increase the downward speed component, that is, the predetermined descent speed control value, based on the horizontal return flight when the UAV, such that the UAV can perform a forced land while returning the flight, thereby saving descent time and improving the flight safety and user experience of the UAV.

As shown in FIG. 2C, the UAV flies from the return flight starting point 221 to the cruising altitude point 222, and controls the UAV to return on the horizontal return flight route 223. If the remaining power of the UAV when flying to the descent point 224 is less than or equal to the predetermined descent power threshold, the UAV may be controlled to perform a forced landing and return the flight in the horizontal direction and the downward perpendicular direction to the horizontal direction. When the UAV descends to the safe altitude point 224, the UAV can be controlled to return horizontally, and when the horizontal return reaches the landing point 226, it will land on the return flight point 227.

The following is a description of the UAV return flight control method in conjunction with the accompanying drawing.

Referring to FIG. 3, which is a flowchart of a UAV return flight control method according to an embodiment of the present disclosure. The method may be executed by the UAV return flight control device, where the specific explanation of the UAV return flight control device is as described above. The UAV return flight control method of the embodiments of the present disclosure will be described in detail below.

S301, controlling the UAV to fly to a predetermined cruising altitude and controlling the UAV to return horizontally at the predetermined cruising altitude based on a first predetermined horizontal speed control value when it is determined that the remaining power of the UAV is less than or equal to a predetermined return flight power threshold.

In the embodiments of the present disclosure, the UAV return flight control device may obtain the UAV's remaining power in real time. When it is determined that the UAV's remaining power is less than or equal to the predetermined return flight power threshold, the UAV return flight control device can control the UAV to fly to the predetermined cruising altitude and control the UAV to return horizontally at the predetermined cruising altitude based on a first predetermined horizontal speed control value.

S302, in the process of returning horizontally at the cruising altitude, controlling the UAV to perform a forced landing and a return flight based on the first predetermined horizontal speed control value and a predetermined descent speed control value when it is determined that the remaining power of the UAV is less than or equal to a predetermined descent power threshold.

In the embodiments of the present disclosure, when the UAV returns horizontally at the cruising altitude, if the UAV return flight control device determines that the UAV's remaining power is less than or equal to the predetermined descent power threshold, the UAV can be controlled to perform a forced landing and return the flight based on the first predetermined horizontal speed control value and the predetermined descent speed control value.

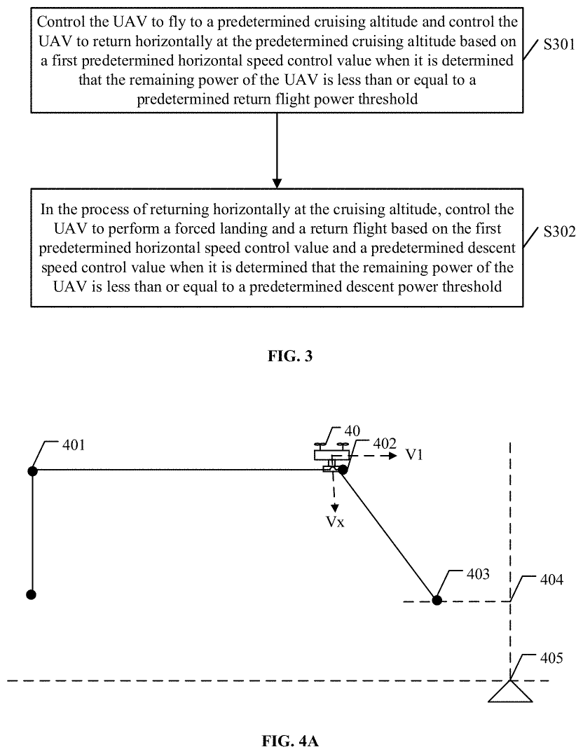

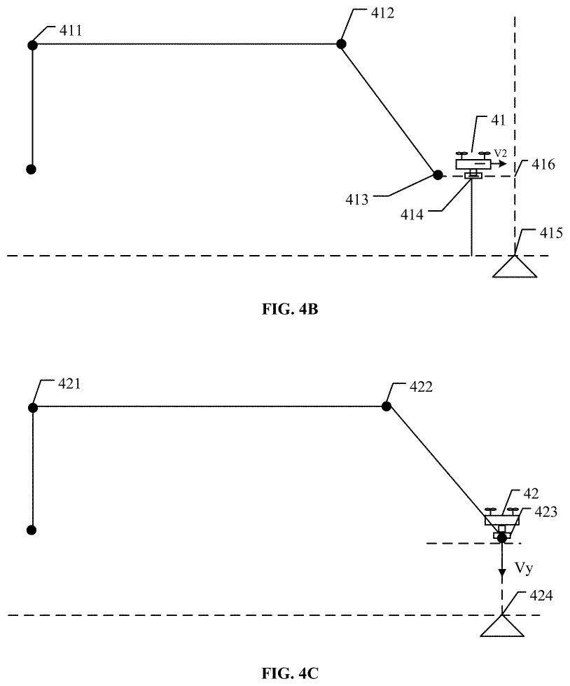

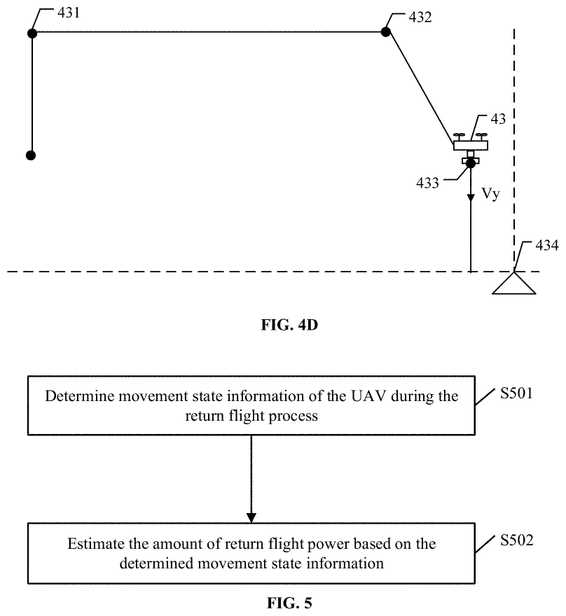

A specific example can be illustrated in FIG. 4A, which is a schematic diagram of another UAV forced landing and return flight method according to an embodiment of the present disclosure. FIG. 4A includes a UAV 40, a cruising altitude point 401, a descent point 402, a safe altitude point 403, a landing point 404, and a return flight point 405, where the cruising altitude point 401 corresponds to the predetermined cruising altitude, and the safe altitude point 403 corresponds to the predetermined safe altitude. Assume the first predetermined horizontal speed control value is V1, when the UAV returns from the cruising altitude point 401 to the descent point 402 along the predetermined cruising altitude level with the first predetermined horizontal speed control value V1, if the UAV return flight control device determines that the remaining power of the UAV 40 is less than or equal to the predetermined descent power threshold, then the UAV can be controlled to perform the forced landing and return flight based on the first predetermined horizontal speed control value V1 and a predetermined descent speed control value Vx.

In one embodiment, in the process of performing the forced landing and return flight, if the UAV return flight control device determines that the UAV's altitude has dropped to the predetermined safe altitude, then the UAV may be controlled to return horizontally at the predetermined safe altitude based on a second predetermined horizontal speed control value. In some embodiments, the first predetermined horizontal speed control value may be the same as the second predetermined horizontal speed control value. In other embodiments, the first predetermined horizontal speed control value may also be different from the second predetermined horizontal speed control value, which is not limited in the embodiments of the present disclosure.

A specific example can be illustrated in FIG. 4B, which is a schematic diagram of another UAV forced landing and return flight method according to an embodiment of the present disclosure. FIG. 4B includes a UAV 41, a cruising altitude point 411, a descent point 412, a safe altitude point 413, a landing point 414, and a return flight point 415, where the cruising altitude point 411 corresponds to the predetermined cruising altitude, and the safe altitude point 413 corresponds to the predetermined safe altitude. Assume the second predetermined horizontal speed control value is V2, when the UAV 41 performs the forced landing and return flight from the descent point 412, if the UAV return flight control device determines that the altitude of the UAV 41 has dropped to a safe altitude point 413, then the UAV 41 can be controlled to perform the return flight at the predetermined safe altitude starting from the safe altitude point 413 based on the second predetermined horizontal speed control value V2.

In one embodiment, when the UAV returns horizontally at the predetermined safe altitude, if the UAV return flight control device determines that the remaining power of the UAV is less than or equal to the predetermined landing power threshold, then the UAV can be controlled to land. In some embodiments, the position point where the remaining power of the UAV is less than or equal to the predetermined landing power threshold may be any position point on the horizontal route at the predetermined safe altitude.

Take FIG. 4B as an example, when the UAV 41 returns horizontally from the safe altitude point 413 along the predetermined safe altitude with the second predetermined horizontal speed control value V2, if the UAV return flight control device determines at the landing point 414 that the remaining power of the UAV 41 is less than or equal to the predetermined landing power threshold, then the UAV can be controlled to land from the landing point 414.

In one embodiment, when the UAV returns horizontally at the predetermined safe altitude, if the UAV return flight control device determines that the UAV reaches above the return flight point, it may control the UAV to land to the return flight point.

Take FIG. 4B as an example, when the UAV 41 returns horizontally from the safe altitude point 413 along the predetermined safe altitude with the second predetermined horizontal speed control value V2, if the UAV return flight control device determines that the UAV 41 has reached the landing point 416 above the return flight point 415, then the UAV 41 can be controlled to land form the landing point 416 to the return flight point 415.

In one embodiment, when the UAV is performing the forced landing and return flight, if the UAV return flight control device determines that the UAV has reached above the return flight point, it can control the UAV to land on the return flight point. In some embodiments, when the UAV is performing the forced landing and return flight, if the UAV return flight control device determines that the has reached above the return flight point when it descends to the predetermined safe altitude, it can control the UAV to land on the return flight point.

A specific example can be illustrated in FIG. 4C, which is a schematic diagram of another UAV forced landing and return flight method according to an embodiment of the present disclosure. FIG. 4C includes a UAV 42, a cruising altitude point 421, a descent point 422, a landing point 423, and a return flight point 424, where the cruising altitude point 421 corresponds to the predetermined cruising altitude, and the landing point 423 is positioned at the predetermined safe altitude above the return flight point. When the UAV 42 descends from the descent point 422, if the UAV return flight control device determines that the UAV has descended to the landing point 423 of the predetermined safe altitude, it can control the UAV 42 to land on the return flight point 424.

In one embodiment, when the UAV performs the forced landing and return flight, if the UAV return flight control device determines that the UAV's remaining power is less than or equal to the predetermined landing power threshold, then the UAV can be controlled to land.

A specific example can be illustrated in FIG. 4D, which is a schematic diagram of another UAV forced landing and return flight method according to an embodiment of the present disclosure. FIG. 4D includes a UAV 43, a cruising altitude point 431, a descent point 432, a landing point 433, and a return flight point 434. When the UAV 43 descends from the descent point 432 to perform the return flight, if the UAV return flight control device determines that the remaining power of the UAV is less than or equal to the predetermined landing power threshold, then the UAV 43 can be controlled to start landing from the landing point 433.

In the embodiments of the present disclosure, the UAV return flight control device can control the UAV to fly to the predetermined cruising altitude when it determines that the remaining power of the UAV is less than or equal to the predetermined return flight power threshold, and control the UAV to return horizontally at the predetermined cruising altitude based on the first predetermined horizontal speed control value. During the horizontal return at the predetermined cruising altitude, when it is determined that the remaining power of the UAV is less than or equal to the predetermined descent power threshold, the UAV can be controlled to perform the forced landing and return flight based on the first predetermined horizontal speed control value and the predetermined descent speed control value. By using this method, the probability of losing the UAV is can be reduced, the descent time can be reduced, and the accuracy and the flight safety of the UAV return flight can be improved.

Referring to FIG. 5, which is a flowchart of a UAV return flight power estimation method according to an embodiment of the present disclosure. The UAV return flight power estimation method can be executed by a UAV return flight power estimation device. A two-way communication may be established between the UAV return flight power estimation device and the UAV, and the UAV return flight power estimation device may be disposed on the UAV. In some embodiments, the UAV return flight power estimation device can be spatially independent from the UAV. In some embodiments, the UAV return flight power estimation device can be a component of the UAV, that is, the UAV may include the UAV return flight power estimation device, and the UAV return flight power estimation device may be the flight controller of the UAV. In other embodiments, the UAV return flight power estimation method can also be applied to other movable devices, such as robots capable of autonomous movement, unmanned vehicles, unmanned ships, and other movable devices, which are not specifically limited in the embodiments of the present disclosure. The UAV return flight power estimation method will be described in detail below.

S501, determining movement state information of the UAV during the return flight process.

In the embodiments of the present disclosure, the UAV return flight power estimation device needs to estimate the UAV return flight power in real time during the flight of the UAV, and the return flight power may be the power needed for the UAV to return from the current position to the return flight point. The UAV return flight power estimation device may determine the movement state information of the UAV during the return flight process. Specifically, during the flight of the UAV, the UAV return flight power estimation device may determine the movement state information of the UAV in the return flight process form the current position to the return flight point in real time. In some embodiments, the movement state information may include at least one of the horizontal flight speed, vertical flight speed, and altitude information of the UAV, where the altitude information of the UAV may include the altitude of the UAV or the height of the UAV relative to the ground. In some embodiments, the return flight process may be the process of the UAV returning from the current position to the return flight point. Take FIG. 2C as an example, assume the current position of the UAV is the return flight starting point 221, the return flight process is the process in which the UAV 40 returns from the return flight starting point 221 to the return flight point 227.

S502, estimating the amount of return flight power based on the determined movement state information.

In the embodiments of the present disclosure, the UAV return flight power estimation device may estimate the return flight power based on the determined movement state information.

The conventional return flight power estimations generally use the power consumption per unit of time obtained based on experience multiplied by the time needed for the return flight. Since the conventional return flight power estimations do not consider the UAV's movement state information during the return flight process, it cannot accurately reflect the impact of the power consumption and cannot cover various flight scenarios. In some scenarios, the estimation result can deviate from the actual situation and the accuracy is poor, especially when the flight distance is long, the difference between the actual return flight power consumption and the estimated return flight power consumption is more obvious. In the embodiments of the present disclosure, the return flight power can be estimated based on the movement state information determined by the UAV during the return flight process, which can truly reflect the impact of the UAV's movement state information on the power consumption during the return flight process, and can accurately estimate the return flight power consumption.

In one embodiment, when the UAV return flight power estimation device estimates the return flight power based on the determined movement state information, the power consumption per unit of time of the UAV during the return flight process can be determined based on the determined movement state information, and the amount of return flight power can be estimated based on the power consumption per unit of time.

More specifically, since the UAV may have different movement state information at different times during the return flight process of the UAV, the UAV may determine the power consumption per unit of time of the UAV based on the movement state information. It can be understood that, since the movement state information of the UAV may be different at different times, the power consumption per unit of time of the UAV may be different at different times. After determining the power consumption per unit of time of the UAV during the return flight process, the return flight power consumption can be determined based on the power consumption per unit of time. For example, the power consumption per unit of time can be accumulated during the return flight process, and the power consumption during the entire return flight process can be estimated based on the cumulative calculation, that is, the amount of return flight power.

In one embodiment, the return flight point may substitute the determined movement state information into the UAV's power consumption model per unit of time to determine the power consumption per unit of time. In some embodiments, the power consumption mode per unit of time of the UAV may be as follow.

Δbatᵣₑₛᵤₘₑ=R1+R2Vᵥₑᵣₜ+R3h+R4V_{horz}7

where Vᵥₑᵣₜ, h, and V_{horz} represent the vertical flight speed, altitude, and horizontal flight speed, respectively. R1, R2, R3, and R4 are model coefficients, where the model coefficients are parameters other than independent variables in the power consumption model per unit of time of the UAV, and Δbatᵣₑₛᵤₘₑ is the power consumption per unit of time. In some embodiments, for the method of establishing the power consumption model per unit of time of the UAV, reference may be made to the later part of the present disclosure, and the UAV return flight power estimation device may be configured to execute the method of establishing the power consumption model per unit of time of the UAV described in later in the present disclosure.

In the embodiments of the present disclosure, the UAV return flight power estimation device can determine the movement state information of the UAV during the return flight process, and estimate the return flight power based on the determined movement state information, By using this method to estimate the return flight power, the error in power estimation can be reduced, and the flight safety and user experience of the UAV can be improved.

Referring to FIG. 6, which a flowchart of a method for establishing a UAV power consumption model per unit of time according to an embodiment of the present disclosure. The method for establishing a UAV power consumption model per unit of time can be executed by a device that can establish a power consumption model per unit of time of the UAV. The device for establishing the power consumption model per unit of time of the UAV may carry out a two-way communication with the UAV, and the device for establishing the power consumption model per unit of time of the UAV may be disposed on the UAV. In some embodiments, the device for establishing the power consumption model per unit of time of the UAV can be spatially independent from the UAV. In some embodiments, the device for establishing the power consumption model per unit of time of the UAV can be a component of the UAV, that is, the UAV may include the device for establishing the power consumption model per unit of time of the UAV, and the device for establishing the power consumption model per unit of time of the UAV may be the flight controller of the UAV. In other embodiments, the method for establishing the power consumption model per unit of time of the UAV can also be applied to other movable devices, such as robots capable of autonomous movement, unmanned vehicles, unmanned ships, and other movable devices, which are not specifically limited in the embodiments of the present disclosure. In some embodiments, the device for establishing the power consumption model per unit of time of the UAV may be a terminal device, where the terminal device may include at least one of a smart phone, a tablet computer, a laptop computer, and a desktop computer. The method for establishing the power consumption model per unit of time of the UAV will be described in detail below.

S601, obtaining the movement state information of the UAV during the flight and the actual power consumption per unit of time corresponding to the movement state information.

In the embodiments of the present disclosure, the device for establishing the power consumption model per unit of time of the UAV may obtain the movement state information of the UAV during the flight, and obtain the actual power consumption per unit of time corresponding to the movement state information, that is, samples of the movement state information and samples of the power consumption per unit of time.

In some embodiments, the movement state information may include the movement state information of the UAV in a plurality of different flight states. In some embodiments, the plurality of different flight states may include at least two of hovering, uniform flight, accelerated flight, and decelerated flight.

In some embodiments, the movement state information may include the movement state information of the UAV in a plurality of different flight environments. In some embodiments, the plurality of different flight environments may include any one or more of a plurality of different positions, a plurality of different flying altitudes, a plurality of different temperature environments, a plurality of different wind speed environments, and the like.

In some embodiments, the movement state information may include a degree of dispersion, and the degree of dispersion of the movement state information may be greater than or equal to a predetermined degree of dispersion threshold. In some embodiments, the movement state information of the UAV may include at least one of the horizontal flight speed, the vertical flight speed, and the altitude information of the UAV.

In some embodiments, the sample of the movement state information and the sample of the power consumption per unit of time can be obtained based on a large amount of sample data, where the device for estimating the UAV return flight power may determine the validity of the sample data before collecting the sample data. In one embodiment, the device for estimating the UAV return flight power may detect whether the flight state of the UAV for which the sample data is obtained is normal. If it is detected that there is no obvious failure in the flight state of the UAV, the flight state of the UAV may be determined as normal. In one embodiment, the device for estimating the UAV return flight power may detect whether the UAV's flight state is maintaining a stable hover, horizontal uniform flight, or vertical uniform flight. If the detection result is positive, the fight state of the UAV can be determined as normal. In one embodiment, after detecting that the flight state of the UAV is normal, the device for estimating the UAV return flight power may start to collect the sample data.

S602, substituting the movement state information into the power consumption per unit of time model to obtain an expected power consumption per unit of time of the UAV.

In the embodiments of the present disclosure, the power consumption per unit of time model may include one or more model coefficients to be determined. After one or more model coefficients to be determined are determined, the power consumption per unit of time model has been successfully established, and the independent variable of the power consumption per unit of time model may be the independent variable of the movement state information. The device for establishing the power consumption per unit of time model of the UAV may substituted the movement state information into the power consumption per unit of time model to obtain the expected power consumption per unit of time model of the UAV.

In one embodiment, the power consumption per unit of time Δbatᵣₑₛᵤₘₑ described above, for the entire UAV return flight process, the device for establishing the power consumption per unit of time model of the UAV can obtain the power needed for the return of the UAV based on the current altitude and the position of the set safe return flight point, the predetermined cruising altitude, the cruising speed, the descent speed, and other return flight information integrated to calculate the return flight time.

S603, running a minimization fitting algorithm based on the actual power consumption per unit of time and the expected power consumption per unit of time to determine the one or more model coefficients to be determined, and updating the power consumption per unit of time model by using the determined model coefficients.

In the embodiments of the present disclosure, the device for establishing the power consumption per unit of time model of the UAV can obtain a plurality of pieces of movement state information, such as the movement state information of the UAV at a plurality of different times during flight, and obtain a plurality of expected power consumptions per unit of time based on the aforementioned method by substituting the plurality of pieces of movement state information into the power consumption per unit of time model including the model coefficients to be determined. The device for establishing the power consumption per unit of time model of the UAV can obtain a plurality of actual power consumptions per unit of time corresponding to the plurality of pieces of movement state information, run a minimization fitting algorithm based on the plurality of actual power consumptions per unit of time and the plurality of expected power consumptions per unit of time to determine the one or more model coefficients to be determined, and update the power consumption per unit of time model by using the determined model coefficients. In some embodiments, the actual power consumption per unit of time may be obtained based on a predetermined unit of time. The embodiments of the present disclosure do not specifically limit the type of the minimization fitting algorithm, and those skilled in the art can select the minimization fitting algorithm based on needs, such as a linear fitting algorithms, a laser square fitting algorithm, etc. After the one or more model coefficients to be determined are determined, the determined model coefficients can be used to update the power consumption per unit of time model of the UAV to successfully establish the power consumption per unit of time model.

In one embodiment, the device for establishing the power consumption per unit of time model of the UAV can obtain the vertical flight speed, the altitude, and the horizontal flight speed, and obtain the actual power consumption per unit of time corresponding to the vertical flight speed, the altitude h, and the horizontal flight speed. The vertical flight speed, the altitude, and the horizontal flight speed can be substituted into the power consumption per unit of time model Δbatᵣₑₛᵤₘₑ=R1+R2Vᵥₑᵣₜ+R3h+R4V_{horz} to calculate the expected power consumption per unit of time Δbatᵣₑₛᵤₘₑ Finally, as described in the above method, a minimization fitting algorithm can be run based on the expected power consumption per unit of time Δbatᵣₑₛᵤₘₑ and the actual power consumption per unit of time to determine the one or more model coefficients R1, R2, R3, and R4 to be determined, and use the determined model R1, R2, R3, and R4 to update the power consumption per unit of time model.

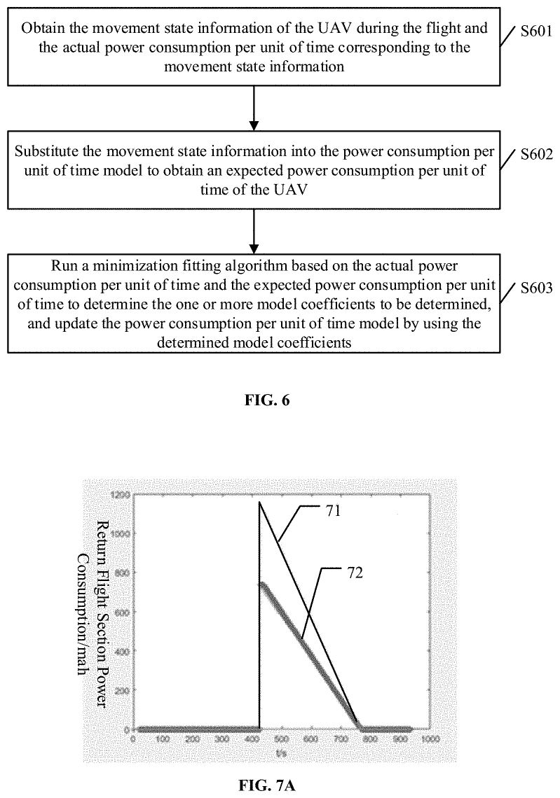

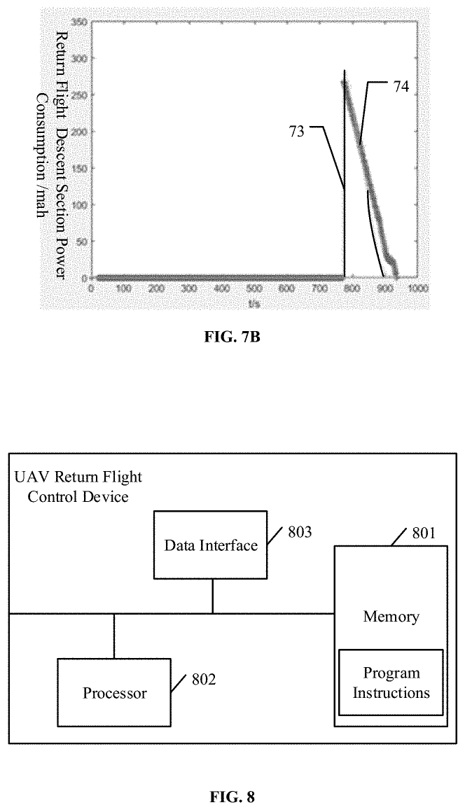

In one embodiment, when estimating the UAV return flight power based on the determined movement state information, the device for estimating the return flight power of the UAV may substitute the determined movement state information at the predetermined cruising altitude into the power consumption per unit of time model of the UAV to estimate the power consumption per unit of time of the UAV at the predetermined cruising altitude. As shown in FIG. 7A, which is an effective diagram of an estimated power consumption per unit of time at a predetermined cruising altitude according to an embodiment of the present disclosure. FIG. 7A includes an original model power consumption 71 and an actual power consumption 72.

In one embodiment, when estimating the UAV return flight power based on the determined movement state information, the device for estimating the return flight power of the UAV may substitute the determined movement state information of the forced landing and return flight into the power consumption per unit of time model of the UAV to estimate the power consumption per unit of time of the UAV at the predetermined cruising altitude. As shown in FIG. 7B, which is an effective diagram of an estimated power consumption per unit of time during a forced landing and return flight according to an embodiment of the present disclosure. FIG. 7B includes an original model power consumption 73 and an actual power consumption 74. As can be seen from FIG. 7A and FIG. 7B, the power consumption per unit of time model of the UAV provided by the embodiments of the present disclosure is more accurate than the conventional model, which shows that the accuracy of the return flight power estimated by the power consumption per unit of time model of the UAV provided by the embodiments of the present disclosure is higher.

In the embodiments of the present disclosure, the device for establishing the power consumption per unit of time model of the UAV can obtain the movement state information of the UAV during the flight and the actual power consumption per unit of time corresponding to the movement state information, and substitute the movement state information into the power consumption per unit of time model to obtain the expected power consumption per unit of time of the UAV. Further, the device for establishing the power consumption per unit of time model of the UAV can run a minimization fitting algorithm based on the actual power consumption per unit of time and the expected power consumption per unit of time to determine the one or more model coefficients to be determined, and update the power consumption per unit of time model by using the determined model coefficients. By using this method, the error in estimating the return flight power can be reduced, the accuracy of the model can be improved, and the flight safety and user experience of the UAV can be improved.

Referring to FIG. 8, which is a schematic structural diagram of a UAV return flight control device according to an embodiment of the present disclosure. More specifically, the UAV return flight control device includes a memory 801, a processor 802, and a data interface 803.

The data interface 803 can be used to transfer data of between the UAV return flight control device and the UAV.

The memory 801 may include a volatile memory. The memory 801 may also include a non-volatile memory. The memory 801 may further include a combination of the foregoing types of memories. The processor 802 may be a central processing unit (CPU). The processor 802 may further include a hardware chip. The hardware chip may be an application-specific integrated circuit (ASIC), a programmable logic device (PLD), or a combination thereof. The PLD may be a complex programmable logic device (CPLD), a field-programmable gate array (FPGA), or any combination thereof.

The memory 801 can be configured to store program instructions. The processor 802 can be configured to execute the program instructions stored in the memory 801. When executed by the processor 802, the program instructions can cause the processor 802 to control the UAV to fly to a predetermined cruising altitude and controlling the UAV to return horizontally at the predetermined cruising altitude based on a first predetermined horizontal speed control value when it is determined that the remaining power of the UAV is less than or equal to a predetermined return flight power threshold; and during the horizontal return flight at the predetermined cruising altitude, control the UAV to perform forced landing and return flight based on the first predetermined horizontal speed control value and the predetermined descent speed control value when determining the remaining power of the UAV is less than or equal to the predetermined landing power threshold.

In some embodiments, the target waypoint that satisfies the predetermined position relationship with the position of the UVA may be the target waypoint that is closest to the position of the UAV.

In some embodiments, when executed by the processor 802, the program instructions can further cause the processor 802 to control the UAV to return horizontally at the predetermined safe altitude based on the second predetermined horizontal speed control value when determining that the altitude of the UAV has dropped to the predetermined safe altitude in the process of forced landing and return flight.

In some embodiments, when executed by the processor 802, the program instructions can further cause the processor 802 to control the UAV to land when determining that the remaining power of the UAV is less than or equal to the predetermined landing power threshold in the process of horizontal return at the predetermined safe altitude.

In some embodiments, when executed by the processor 802, the program instructions can further cause the processor 802 to control the UAV to land on the return flight point when determining that the UAV has reached above the return flight point in the process of horizontal return at the predetermined safe altitude.

In some embodiments, when executed by the processor 802, the program instructions can further cause the processor 802 to control the UAV to land on the return flight point when determining that the UAV has reached above the return flight point in the process of forced landing and return flight.

In some embodiments, when executed by the processor 802, the program instructions can further cause the processor 802 to control the UAV to land when determining that the remaining power of the UAV is less than or equal to the predetermined landing power threshold in the process of forced landing and return flight.

In the embodiments of the present disclosure, the UAV return flight control device can control the UAV to fly to a predetermined cruising altitude when it determines that the remaining power of the UAV is less than or equal to the predetermined return flight power threshold, and control the UAV to return horizontally at the predetermined cruising altitude based on the first predetermined horizontal speed control value. In the process of horizontal return at the predetermined cruising altitude, when it is determined that the remaining power of the UAV is less than or equal to the predetermined descent power threshold, the UAV can be controlled to perform the forced land and return flight based on the first predetermined horizontal speed control value and the predetermined descent speed control value. By using this method, the probability of losing the UAV can be reduced, the descent time can be reduced, and the flight safety of the UAV can be improved.

Referring to FIG. 9, which is a schematic structural diagram of a structure of a return flight power estimation device for a UAV according to an embodiment of the present disclosure. More specifically, the return flight power estimation device for the UAV includes a memory 901, a processor 902, and a data interface 903.

The data interface 903 can be used to transfer data of between the UAV return flight control device and the UAV.

The memory 901 may include a volatile memory. The memory 901 may also include a non-volatile memory. The memory 901 may further include a combination of the foregoing types of memories. The processor 902 may be a central processing unit (CPU). The processor 902 may further include a hardware chip. The hardware chip may be an application-specific integrated circuit (ASIC), a programmable logic device (PLD), or a combination thereof. The PLD may be a complex programmable logic device (CPLD), a field-programmable gate array (FPGA), or any combination thereof.

The memory 901 can be configured to store program instructions. The processor 902 can be configured to execute the program instructions stored in the memory 901. When executed by the processor 902, the program instructions can cause the processor 902 to determine the movement state information of the UAV in the process of the return flight, where the process of the return flight may be the process of returning the UAV from the current position to the return flight point; and determining the return flight power based on the determined movement state information.

In some embodiments, the processor 902 executing the program instructions stored in the memory 901 to estimate the return flight power based on the determined movement state information may include determining the power consumption per unit of time of the UAV during the return flight process based on the determined movement state information; and estimating the return flight power based on the power consumption per unit of time.

In some embodiments, the processor 902 executing the program instructions stored in the memory 901 to determine the power consumption per unit of time based on the determined movement state information may include substituting the determined movement state information into the power consumption per unit of time model of the UAV to determine the power consumption per unit of time.

In some embodiments, the movement state information may include at the least one of the horizontal flight speed, the vertical flight speed, and the altitude information of the UAV.

In the embodiments of the present disclosure, the UAV return flight power estimation device can determine the movement state information of the UAV during the return flight process, and estimate the return flight power based on the determined movement state information. By using this method to estimate the return flight power, the error in estimation can be reduced, and the flight safety and user experience of the UAV can be improved.

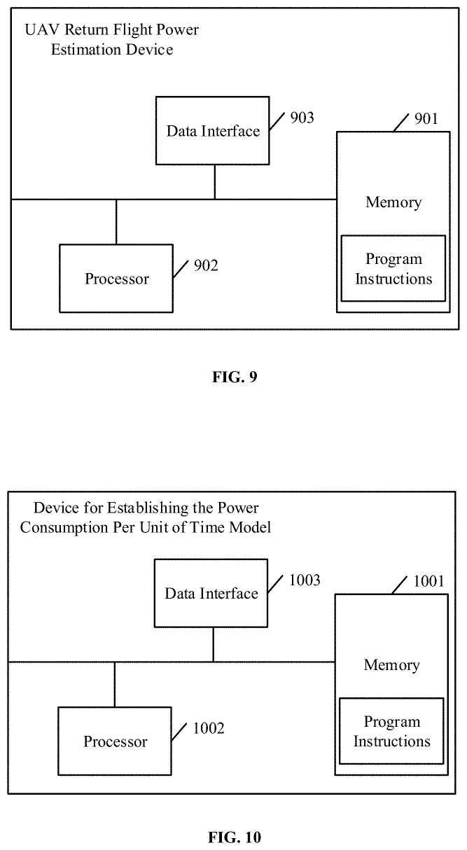

Referring to FIG. 10, which is a schematic structural diagram of a device for establishing a UAV power consumption model per unit of time according to an embodiment of the present disclosure. More specifically, the device for establishing the power consumption per unit of time model includes a memory 1001, a processor 1002, and a data interface 1003.

The data interface 1003 can be used to transfer data of between the UAV return flight control device and the UAV.

The memory 1001 may include a volatile memory. The memory 1001 may also include a non-volatile memory. The memory 1001 may further include a combination of the foregoing types of memories. The processor 1002 may be a central processing unit (CPU). The processor 1002 may further include a hardware chip. The hardware chip may be an application-specific integrated circuit (ASIC), a programmable logic device (PLD), or a combination thereof. The PLD may be a complex programmable logic device (CPLD), a field-programmable gate array (FPGA), or any combination thereof.

The memory 1001 can be configured to store program instructions. The processor 1002 can be configured to execute the program instructions stored in the memory 1001. When executed by the processor 1002, the program instructions can cause the processor 1002 to obtain the movement state information of the UAV during the flight and the actual power consumption per unit of time corresponding to the movement state information; substitute the movement state information into the power consumption per unit of time model to obtain the expected power consumption per unit of time of the UAV, where the power consumption per unit of time model may include one or more model coefficients to be determined; and run a minimization fitting algorithm based on the actual power consumption per unit of time and the expected power consumption per unit of time to determine the one or more model coefficients to be determined, and update the power consumption per unit of time model by using the determined model coefficients.

In some embodiments, the movement state information may include the movement state information of the UAV in a plurality of different flight states.

In some embodiments, the movement state information may include the movement state information of the UAV in a plurality of different flight environments.

In some embodiments, the degree of dispersion of the movement state information may be greater than or equal to the predetermined degree of dispersion threshold.

In some embodiments, the movement state information may include at least one of the horizontal flight speed, the vertical flight speed, and the altitude information of the UAV.

In the embodiments of the present disclosure, the device for establishing the power consumption per unit of time model of the UAV can obtain the movement state information of the UAV during the flight and the actual power consumption per unit of time corresponding to the movement state information, and substitute the movement state information into the power consumption per unit of time model to obtain the expected power consumption per unit of time of the UAV. Further, the device for establishing the power consumption per unit of time model of the UAV can run a minimization fitting algorithm based on the actual power consumption per unit of time and the expected power consumption per unit of time to determine the one or more model coefficients to be determined, and update the power consumption per unit of time model by using the determined model coefficients. By using this method, the error in estimating the return flight power can be reduced, the accuracy of the model can be improved, and the flight safety and user experience of the UAV can be improved.

An embodiment of the present disclosure further provides a UAV. The UAV may include a body, a power system disposed on the body to provide power for the UAV to move, and a processor configured to control the UAV to fly to a predetermined cruising altitude and controlling the UAV to return horizontally at the predetermined cruising altitude based on a first predetermined horizontal speed control value when it is determined that the remaining power of the UAV is less than or equal to a predetermined return flight power threshold; and during the horizontal return flight at the predetermined cruising altitude, control the UAV to perform forced landing and return flight based on the first predetermined horizontal speed control value and the predetermined descent speed control value when determining the remaining power of the UAV is less than or equal to the predetermined landing power threshold.

In some embodiments, the processor may be further configured to control the UAV to return horizontally at the predetermined safe altitude based on the second predetermined horizontal speed control value when determining that the altitude of the UAV has dropped to the predetermined safe altitude in the process of forced landing and return flight.

In some embodiments, the processor may be further configured to control the UAV to land when determining that the remaining power of the UAV is less than or equal to the predetermined landing power threshold in the process of horizontal return at the predetermined safe altitude.

In some embodiments, the processor may be further configured to control the UAV to land on the return flight point when determining that the UAV has reached above the return flight point in the process of horizontal return at the predetermined safe altitude.

In some embodiments, the processor may be further configured to control the UAV to land on the return flight point when determining that the UAV has reached above the return flight point in the process of forced landing and return flight.

In some embodiments, the processor may be further configured to control the UAV to land when determining that the remaining power of the UAV is less than or equal to the predetermined landing power threshold in the process of forced landing and return flight.

In the embodiments of the present disclosure, the UAV return flight control device can control the UAV to fly to a predetermined cruising altitude when it determines that the remaining power of the UAV is less than or equal to the predetermined return flight power threshold, and control the UAV to return horizontally at the predetermined cruising altitude based on the first predetermined horizontal speed control value. In the process of horizontal return at the predetermined cruising altitude, when it is determined that the remaining power of the UAV is less than or equal to the predetermined descent power threshold, the UAV can be controlled to perform the forced land and return flight based on the first predetermined horizontal speed control value and the predetermined descent speed control value. By using this method, the probability of losing the UAV can be reduced, the descent time can be reduced, and the flight safety of the UAV can be improved.

An embodiment of the present disclosure further provides another UAV. The UAV may include a body, a power system disposed on the body to provide power for the UAV to move, and a processor configured to determine the movement state information of the UAV in the process of the return flight, where the process of the return flight may be the process of returning the UAV from the current position to the return flight point; and determining the return flight power based on the determined movement state information.

In some embodiments, the processor estimating the return flight power based on the determined movement state information may include determining the power consumption per unit of time of the UAV during the return flight process based on the determined movement state information; and estimating the return flight power based on the power consumption per unit of time.

In some embodiments, the processor determining the power consumption per unit of time based on the determined movement state information may include substituting the determined movement state information into the power consumption per unit of time model of the UAV to determine the power consumption per unit of time.

Further, the movement state information may include at the least one of the horizontal flight speed, the vertical flight speed, and the altitude information of the UAV.

In the embodiments of the present disclosure, the UAV return flight power estimation device can determine the movement state information of the UAV during the return flight process, and estimate the return flight power based on the determined movement state information. By using this method to estimate the return flight power, the error in estimation can be reduced, and the flight safety and user experience of the UAV can be improved

An embodiment of the present disclosure further provides another UAV. The UAV may include a body, a power system disposed on the body to provide power for the UAV to move, and a processor configured to obtain the movement state information of the UAV during the flight and the actual power consumption per unit of time corresponding to the movement state information; substitute the movement state information into the power consumption per unit of time model to obtain the expected power consumption per unit of time of the UAV, where the power consumption per unit of time model may include one or more model coefficients to be determined; and run a minimization fitting algorithm based on the actual power consumption per unit of time and the expected power consumption per unit of time to determine the one or more model coefficients to be determined, and update the power consumption per unit of time model by using the determined model coefficients.

In some embodiments, the movement state information may include the movement state information of the UAV in a plurality of different flight states.

In some embodiments, the movement state information may include the movement state information of the UAV in a plurality of different flight environments.

In some embodiments, the degree of dispersion of the movement state information may be greater than or equal to the predetermined degree of dispersion threshold.

In some embodiments, the movement state information may include at least one of the horizontal flight speed, the vertical flight speed, and the altitude information of the UAV.

In the embodiments of the present disclosure, the device for establishing the power consumption per unit of time model of the UAV can obtain the movement state information of the UAV during the flight and the actual power consumption per unit of time corresponding to the movement state information, and substitute the movement state information into the power consumption per unit of time model to obtain the expected power consumption per unit of time of the UAV. Further, the device for establishing the power consumption per unit of time model of the UAV can run a minimization fitting algorithm based on the actual power consumption per unit of time and the expected power consumption per unit of time to determine the one or more model coefficients to be determined, and update the power consumption per unit of time model by using the determined model coefficients. By using this method, the error in estimating the return flight power can be reduced, the accuracy of the model can be improved, and the flight safety and user experience of the UAV can be improved.

A computer-readable storage medium is also provided in the embodiments of the present disclosure. The computer-readable storage medium stores a computer program, and the computer program is executed by a processor to implement the methods in the embodiments corresponding to FIG. 1, FIG. 3, FIG. 5, or FIG. 6. The computer-readable storage medium can also implement the devices according to the embodiments of the present disclosure as shown in FIG. 8, FIG. 9, or FIG. 10, and details are not described herein again.

The computer-readable storage medium may be an internal storage unit of the device according to any one of the foregoing embodiments, such as a hard disk or a memory of the device. The computer-readable storage medium may also be an external storage device of the device, such as a plug-in hard disk, a smart media card (SMC), and a secure digital (SD) card, a flash card, etc., provided in the device. Further, the computer-readable storage medium may further include both an internal storage unit of the above device and an external storage device. The computer-readable storage medium is configured to store the computer program and other programs and data required by the terminal. The computer-readable storage medium may also be configured to temporarily store data that has been or will be output.

The above embodiments are only the preferred embodiments of the present disclosure, and of course, and do not limit the claimed scope of the present disclosure. Therefore, equivalent changes made according to the claims of the present disclosure are within the scope of the present disclosure.

What is claimed is:

1. A method for controlling a return flight of an unmanned aerial vehicle (UVA), comprising:
controlling the UAV to fly to a predetermined cruising altitude, and controlling the UAV to return horizontally at the predetermined cruising altitude based on a first predetermined horizontal speed control value when determining that a remaining power of the UVA is less than or equal to a predetermined return flight power threshold; and
controlling the UAV to perform a forced landing and the return flight based on the first predetermined horizontal speed control value and a predetermined descent speed control value when determining that the remaining power of the UAV is less than or equal to a predetermined descent power threshold in the process of the horizontal return at the predetermined cruising altitude.

2. The method of claim 1, further comprising:
controlling the UAV to return horizontally at a predetermined safe altitude based on a second predetermined horizontal speed control value when determining that an altitude of the UAV has dropped to the predetermined safe altitude in the forced landing and return flight process.

3. The method of claim 2, further comprising:
controlling the UAV to land when determining that the remaining power of the UAV is less than or equal to a predetermined landing power threshold in the process of the horizontal return at the predetermined safe altitude.

4. The method of claim 2, further comprising:
controlling the UAV to land on a return flight point when determining that the UAV has reached above the return flight point in the process of the horizontal return at the predetermined safe altitude.

5. The method of claim 1, further comprising:
controlling the UAV to land on the return flight point when determining that the UAV has reached above the return flight point in the forced landing and return flight process.

6. The method of claim 1, further comprising:
controlling the UAV to land when determining that the remaining power of the UAV is less than or equal to the predetermined landing power threshold in the forced landing and return flight process.

7. A device for controlling a return flight of an UAV, comprising:
a processor; and
a memory storing program instructions that, when being executed by the processor, cause the processor to:
control the UAV to fly to a predetermined cruising altitude, and control the UAV to return horizontally at the predetermined cruising altitude based on a first predetermined horizontal speed control value when determining that a remaining power of the UVA is less than or equal to a predetermined return flight power threshold; and
control the UAV to perform a forced landing and the return flight based on the first predetermined horizontal speed control value and a predetermined descent speed control value when determining that the remaining power of the UAV is less than or equal to a predetermined descent power threshold in the process of the horizontal return at the predetermined cruising altitude.

8. The device of claim 7, wherein the processor is further configured to:
control the UAV to return horizontally at a predetermined safe altitude based on a second predetermined horizontal speed control value when determining that an altitude of the UAV has dropped to the predetermined safe altitude in the forced landing and return flight process.

9. The device of claim 8, wherein the processor is further configured to:
control the UAV to land when determining that the remaining power of the UAV is less than or equal to a predetermined landing power threshold in the process of the horizontal return at the predetermined safe altitude.

10. The device of claim 8, wherein the processor is further configured to:
control the UAV to land on a return flight point when determining that the UAV has reached above the return flight point in the process of the horizontal return at the predetermined safe altitude.

11. The device of claim 7, wherein the processor is further configured to:
control the UAV to land on the return flight point when determining that the UAV has reached above the return flight point in the forced landing and return flight process.

12. The device of claim 7, wherein the processor is further configured to:
control the UAV to land when determining that the remaining power of the UAV is less than or equal to the predetermined landing power threshold in the forced landing and return flight process.
